(19) United States
(12) Patent Application Publication
(10) Pub. No.: US 2023/0042495 A1
(43) Pub. Date: Feb. 9, 2023

(54) COARSE AND HIERARCHICAL SWEEP SAMPLING IN MEMORY TRAINING

(71) Applicant: Intel Corporation, Santa Clara, CA (US)

(72) Inventors: Min Liu, Camas, WA (US); Young Xiangguo Guo, Shanghai (CN); Lei Zhu, Shanghai (CN); Yannan Sun, Shanghai (CN); Xiang Li, Shanghai (CN)

(73) Assignees: Intel Corporation, Santa Clara, CA (US); Intel Corporation, Santa Clara, CA (US)

(21) Appl. No.: 17/967,037

(22) Filed: Oct. 17, 2022

(30) Foreign Application Priority Data
Oct. 1, 2022 (CN) PCT/CN2022/123671

(51) Int. Cl. G06F 3/06

(52) U.S. Cl. CPC G06F 3/0632; G06F 3/0625; G06F 3/0679

(57) ABSTRACT

In coarse memory training approaches, a multiple of a base timing interval is used to reduce the sampling time in a sweep sampling approach during memory training to determine the timing offset between a non-clock memory signal and a memory clock to ensure reliable memory operation at high frequencies. In a hierarchical memory training method, a coarse memory training step is employed to determine adjustable timing offsets where a memory captures the rising and falling edges of a non-clock memory signal and those adjustable timing offsets are used in a subsequent fine memory training step to refine the timing offsets where the memory captures the rising and falling edges of the non-clock memory signal. The hierarchical approach can determine timing offsets for non-clock memory signals with the accuracy of existing (non-coarse, non-hierarchical) memory training methods in less time than the existing methods.

### CROSS-REFERENCE TO RELATED APPLICATION

This application claims the benefit of International Application No. PCT/CN2022/123671, filed Oct. 1, 2022.

### BACKGROUND

Memory Reference Code (MRC) is a portion of BIOS (Basic Input/Output System) code that performs memory training on memory signals (such as the CS (chip select) and DQ (data) signals in a DDR (Double Data Rate) memory interface) to ensure that components in the memory pipeline (e.g., processors, memory data buffers, memories) can communicate reliably at high frequencies.

### BRIEF DESCRIPTION OF THE DRAWINGS

FIG. 1 illustrates a first example memory training scenario employing a base timing interval for the adjustable timing offset interval.

FIG. 2 illustrates a second example memory training scenario employing a coarse adjustable timing offset interval.

FIG. 3 illustrates a third example memory training scenario employing a base timing for the adjustable timing offset interval as part of a hierarchical memory training approach.

FIG. 4 is a graph illustrating the dependency of the number of non-clock memory signal samples captured during a hierarchical memory training approach based on the coarseness of the coarse sweep sampling step.

FIG. 5 is an example method of performing coarse memory training.

FIG. 6 is an example method of performing hierarchical memory training.

FIG. 7 a block diagram of an example computing system in which technologies described herein may be implemented.

FIG. 8 is a block diagram of an example processor unit to execute computer-executable instructions as part of implementing technologies described herein.

### DETAILED DESCRIPTION

Computing systems can perform memory training on memory signals during their power-on startup (boot) sequence to ensure that memories can reliably communicate with other components in the computing system at high frequencies. Memory training allows for timing offsets between non-clock memory signals (e.g., chip select, command, data, data strobe) and a memory clock signal to be determined to account for differences in, for example, trace lengths between the non-clock memory signal and the memory clock signal, and integrated circuit component and printed circuit board manufacturing variations. In some systems comprising Intel® integrated circuit components, memory training can be performed by the Memory Reference Code (MRC) portion of BIOS (Basic Input/Output System) code.

The number of signals for which memory training can be performed can be numerous given the number of individual memory signals going to the various memory integrated circuit components in a computing system. The greater the number of memory integrated circuit components (e.g., DIMMs (dual in-line memory modules)) in a computing system, the greater the number of memory signals that are to be trained during power-on startup. In some embodiments, the amount of memory training time spent performing sweep sampling (which will be described in more detail below) can be expressed as follows: total sweep sampling time=socket count*DIMM count*rank count*memory signal count*single signal sample time.

The number of signals for which memory training is to be performed grows even larger in computing systems that employ a memory data buffer (or another component) between a processing unit and a memory. In such systems, memory training can be performed for signals belonging to a front-side memory bus—the signals between the memory data buffer and the memory—and signals belonging to a back-side memory bus—the signals between the processing unit and the memory data buffer. In some computing systems, memory training can take thousands of samples to determine timing offsets for the non-clock memory signals in a system. Thus, the memory training portion of a power-on startup sequence of a computing system can take a long time, which can result in a degraded user experience.

In computing systems for which Memory Reference Code (MRC) executes during a system's power-on startup sequence, the MRC performs the memory training. MRC memory training can contain two parts: basic training and advanced training. Basic training performs the fundamental memory training steps to boot a computing system, including figuring out the correct timing offsets (latencies) to align non-clock memory signals with memory clock signals. MRC can perform memory training on various memory types, including DDR5 RDIMM (Reduced DIMM (Dual In-Line Memory Module)), DDR5 LRDIMM (Load-reduced DIMM), and DDR T2 (DDR Type 2) memories to name a few.

Sweep sampling (which can be used by MCR basic training) is one memory training approach used to determine time offsets to align non-clock memory signals with memory clock signals. In a sweep sampling approach, an adjustable offset timing between rising and falling edges in a non-clock memory signal and a rising edge of a memory clock signal is swept through a range of values and the values of the non-clock memory signal captured by a memory as the adjustable offset timing is varied are sampled. In some embodiments, the range of adjustable offset timings covers the range of one period of the non-clock memory signal being sampled. The adjustable timing offsets at which the memory captures the last “0” value before a non-clock memory signal rising edge (or the first “1” value after the rising edge) is captured and the last “1” value before a non-clock memory signal falling edge (or the first “0” value after the falling edge) is captured are determined and a timing offset for the non-clock memory signal is determined based on these adjustable timing offsets. The timing offset is utilized during operation of the computing system after the system's power-on startup sequence has completed.

Disclosed herein are technologies that can reduce the amount of time spent during a power-on sequence to perform memory training. Coarse, hierarchical, and user-defined adjustable timing offset approaches are disclosed. In coarse memory training approaches, the step size of the adjustable timing offset (adjust timing offset interval) of a non-clock memory signal is a multiple of a base timing interval (e.g., a phase interval). The base timing interval can be an adjustable timing offset interval to be used for memory training that is set in BIOS code and provided by a BIOS provider. The base timing interval can be stored in a computer-readable storage medium that is part of the computing system that will use the base timing interval during memory training in its power-on startup sequence. In hierarchical memory training approaches, in a first step, a sweep sampling uses a coarse adjustable timing offset interval (which can be a multiple of the base timing interval) to determine a rough timing offset window where the non-clock memory signal's rising and falling edges are captured by the memory and in a second step, a fine sweep sampling uses the base timing interval to refine the adjustable timing offsets at which the rising and falling edges are captured. In manual memory training approaches, a user-defined adjustable timing offset interval is used. The user can provide a multiple of the base timing interval that is to be used and can define different multiples to be used for different non-clock memory signals.

The disclosed sweep sampling technologies have at least the following advantages. First, they allow for faster memory training, which can allow a computing device to complete a power-on startup sequence in a shorter amount of time. Second, a user-defined adjustable timing offset interval allows for flexibility in the memory training process over approaches where only a base timing interval is used.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements cooperate or interact with each other, but they may or may not be in direct physical or electrical contact. Furthermore, the terms “comprising,” “including,” “having,” and the like, as used with respect to embodiments of the present disclosure, are synonymous.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the terms “operating”, “executing”, or “running” as they pertain to software or firmware in relation to a system, device, platform, or resource are used interchangeably and can refer to software or firmware stored in one or more computer-readable storage media accessible by the system, device, platform or resource, even though the software or firmware instructions are not actively being executed by the system, device, platform, or resource.

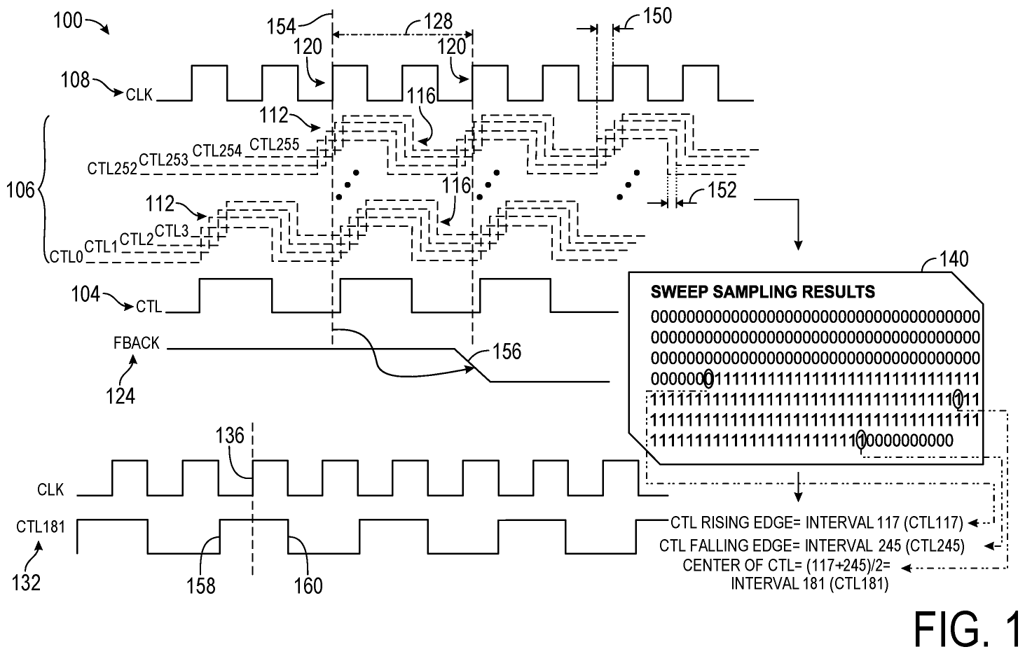

FIG. 1 illustrates a first example memory training scenario employing a base timing interval for the adjustable timing offset interval. Generally, scenario 100 illustrates determining the timing offset for a non-clock memory signal (CTL signal 104) relative to a memory clock signal (CLK signal 108) using a sweep sampling approach. The sweep sampling approach asserts cycles of the non-clock memory signal to a memory with rising edge edges and falling edges of the non-clock memory signal offset from the memory clock signal asserted to the memory by an adjustable timing offset. The adjustable timing offset is adjusted by a base timing interval (or phase interval) after one or more cycles of the non-clock memory signal are asserted to produce a non-clock memory signal sample for a particular adjustable timing offset. The sample indicates the value of the non-clock memory signal captured by the memory. After the sweep sampling approach has swept through the various values for the adjustable timing offset, the timing offset for the non-clock memory signal is determined from the samples of the non-clock memory signal values captured by the memory. In some embodiments, the range of values for the adjustable timing offset covers one period of the non-clock memory signal being sampled. The timing offset is based on the adjustable timing offset at which the memory captured the rising edge of the non-clock memory signal (the adjustable timing offset at which the memory captured the last “0” before the first “1” was captured or the first “1” after the last “0” was captured) and the adjustable timing offset at which the memory captured the falling edge of the non-clock memory signal (the adjustable timing offset at which the memory captured the last “1” before the first “0” was captured or the first “0” after the last “1” was captured). The determined timing offset is then utilized during operation of the computing system after the system's power-on startup sequence has completed. In some embodiments, the timing offset is the average of these two adjustable timing offsets. The base timing interval can be based on the period of a reference signal and a number of divisions that the reference signal period is to be divided by to determine the base timing interval.

With reference to determining the timing offset of the CTL signal 104, the memory training scenario 100 comprises a sweep sampling approach that asserts cycles of the CTL signal to a memory with rising edges 112 and falling edges 116 of the CTL signal offset from rising edges 120 of the CLK signal 108 by an adjustable timing offset 150. The reference signal for the base timing interval is the CLK signal 108 and the reference signal is to be divided into 128 parts to determine the base timing interval 152. As the period 128 of the CTL signal 104 is twice that of the CLK signal 108, a period of the CTL signal 104 comprises 256 base timing intervals, and 256 different CTL waveforms 106 (CTL0 through CTL255) are asserted to the memory during sweep sampling, with each waveform 106 comprising rising and falling edges offset from an edge of the CLK signal 108 by a different adjustable timing offset 150. The value of the CTL signal captured by the memory during a single signal sampling time is represented by a FBACK signal 124 provided by the memory. For example, the rising edge 120 of the CLK signal represented by line 154 causes a transition 156 of the FBACK signal 124.

Sweep sampling results 140 illustrate the 256 values of the CTL signal captured by the memory for the 256 CTL waveforms 106. The rising edge of the CTL signal was captured by the memory at the 117th CTL waveform (CTL117) and the falling edge of the CTL signal was captured at the 245th CTL waveform (CTL245). The timing offset for the CTL signal is thus determined to be 181 times the base timing interval (the average of the 117th and 245th adjustable timing offset values), represented by CTL181 waveform 132. FIG. 1 illustrates that the timing offset determined for the CTL signal results in the CLK rising edges 136 being centered between the rising 158 and falling edges 160 of the CTL signal 132.

The timing offset for the CTL signal 104 can be translated from a number of base timing intervals to a time based on the period of the reference signal. For example, in DDR5 memories, the memory clock signal can have a frequency of 2.4 GHz, which corresponds to a period of 416.7 ps. With 128 divisions, the base timing interval is 3.26 ps (416.7 ps/128). The timing offset of the CTL signal 104 is 181 base timing intervals, which translates to a timing offset of 589 ps. With a timing offset for the CTL signal determined by the memory training scenario 100, it can be utilized by the computing system after the system's power-on startup sequence has completed when asserting the CTL signal to the memory.

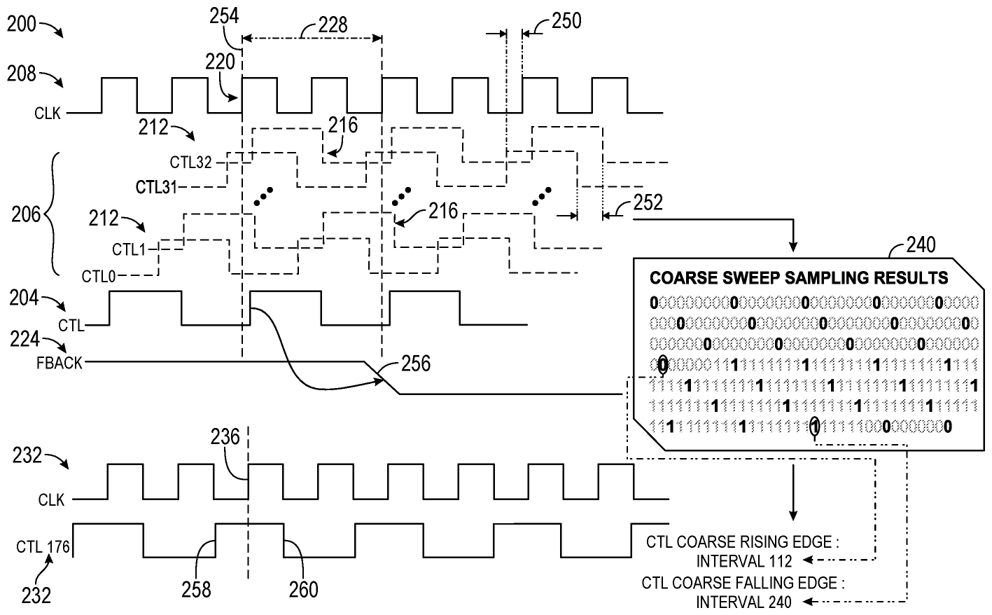

FIG. 2 illustrates a second example memory training scenario employing a coarse adjustable timing offset interval. In the scenario 200, the adjustable timing offset is increased by an adjustable timing offset interval that is a multiple N of a base timing interval. The base timing interval based on a reference signal and a number of divisions of the reference signal is to be divided into to determine the base timing value. Thus, in a coarse memory training scenario, the overall sweep sampling time can be approximately N times faster than a memory training approach where the adjustable timing offset is adjusted by the base timing interval. The scenario 200 illustrates determining the timing offset for a CTL signal 204 relative to a memory clock signal CLK 208. The adjustable timing offset 250 is adjusted by an adjustable timing offset interval that is a multiple N of the base timing interval after assertion of one or more cycles of the CTL signal 204 used to generate a CTL signal sample. In scenario 200, N is set to 8. Thus, a set of 33 CTL waveforms 206 (CTL0 through CTL32) are applied to the memory, the rising 212 and falling 216 edges of successively applied CTL waveforms 206 adjusted by a timing interval 252 that is eight times the base timing interval. The 33 CTL waveforms 206 are roughly a factor of eight less than the 256 CTL waveforms 106 asserted in the memory training scenario 100. The value of the CTL signal 204 captured by the memory is represented by a FBACK signal 224.

Sweep sampling results 240 show the 33 samples generated by the 33 CTL waveforms 206 that represent shifting the CTL waveforms 206 over one full CTL cycle during the memory training scenario 200. 256 base timing intervals are represented in the sweep sampling results 240 with every eighth number in boldface to represent that in the coarse memory training scenario 200 a CTL sample is captured only every eight base timing intervals. The sweep sampling results 240 show that the rising edge of the CTL signal was captured during assertion of the CTL14 waveform, which corresponds to 112 base timing intervals (14th adjustable timing offset interval*8 base timing intervals/adjustable timing offset interval) and the falling edge of the CTL signal was captured during assertion of the CTL30 waveform, which corresponds to 240 base timing intervals. Thus, the timing offset for the CTL signal 204 is determined to be 176 times the base timing interval ((112+240)/2=176), represented by CTL176 waveform 232. FIG. 2 illustrates that the timing offset determined for the CTL signal results in the CLK rising edges 236 being centered between the rising 258 and falling edges 260 of the CTL signal 232. With a reference clock frequency of 2.4 GHz divided into 128 parts, the timing offset of the CTL signal 204 determined by a coarse memory training approach is 176 base timing intervals, which translates to a timing offset of 573 ps.

In a hierarchical memory training approach, a coarse sweep sampling step, such as that illustrated in FIG. 2 is followed by a fine sweep sampling step. The adjustable timing offsets determined in the coarse sweep sampling at which the memory captures the rising and falling edges of the non-clock memory signal are used as starting offset times for the adjustable timing offsets in the fine sweep sampling step to refine the timing offset at which the memory captures the rising edge and falling edges of the non-clock memory signal.

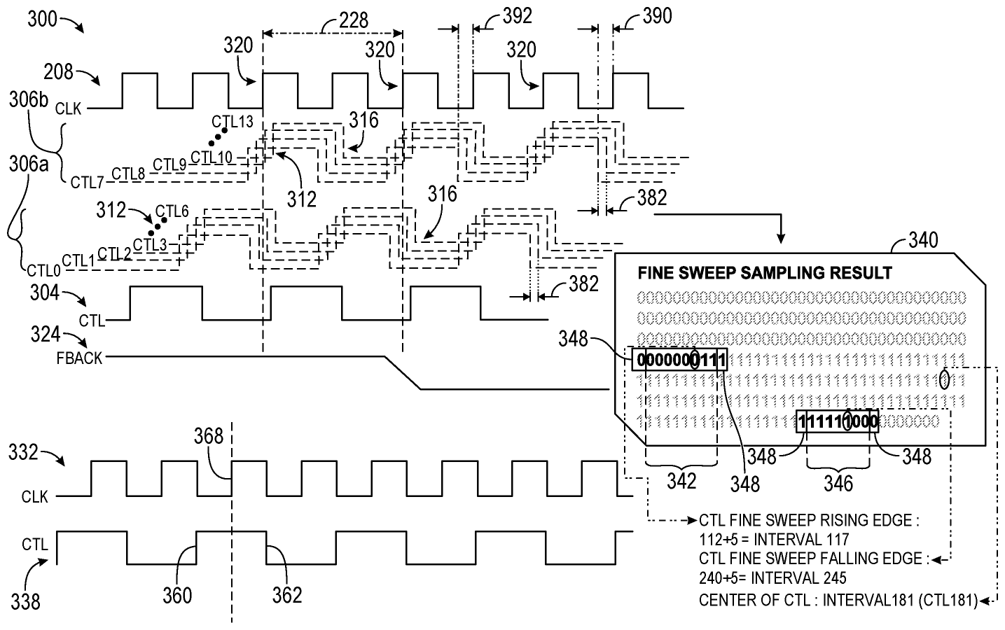

FIG. 3 illustrates a third example memory training scenario employing a base timing for the adjustable timing offset interval as part of a hierarchical memory training approach. The scenario 300 comprises a fine sweep sampling step for a hierarchical memory training approach based on the results of the coarse sweep sampling scenario of FIG. 2. The coarse sweep sampling in FIG. 2 determined that the rising and falling edges of the CTL signal 204 were captured at the 112th and 240th adjustable timing offsets. The fine sweep sampling step comprises two sweeps of the adjustable timing offsets to refine the timing offsets at which the rising and falling edges of the CTL signal 204 are captured by the memory.

In the first fine sweep, the adjustable timing offset starts at the 112th adjustable timing offset and comprises asserting a first set of seven CTL signal waveforms 306a (CTL0-CTL6). In the second fine sweep, the adjustable timing offset starts at the 240th adjustable timing offset and comprises asserting a second set of seven CTL signal waveforms 306b (CTL7-CTL13). Seven CTL waveforms are asserted in the first and second fine sweeps as that is the number of samples not generated at base timing intervals between successive samples generated by the coarse sweep sampling step. That is, seven samples at the base timing interval are not generated in successive samples in a coarse sweep sampling in which samples are generated every eighth base timing interval. An ending timing offset time for an adjustable timing offset for a fine sweep sampling can be the multiple for the base timing interval specified in the coarse sweep sampling step minus one.

Fine sweep sampling results 340 show the samples 342 generated by the first fine sweep and the samples 346 generated by the second fine sweep in addition to the samples 348 generated by the coarse sweep indicating the capture of the rising edge and falling edges of the CTL signal 204 during the coarse sweep. The fine sweep sampling results 340 indicate capture of the rising edge of the CTL 204 during assertion of the waveforms 306a at the 117th adjustable timing offset and capture of the falling edge of the CTL signal 204 during assertion of the waveforms 306b at the 245th adjustable timing offset. The timing offset of the CTL signal 204 using the hierarchical approach comprising the coarse sweep sampling step illustrated in scenario 200 and the fine sweep sampling step illustrated in scenario 300 is thus 181 base timing intervals. CTL signal 338, which is offset from CLK signal 332 by 181 base timing intervals, shows that the rising 360 and falling 362 edges of the CTL signal 338 are centered about rising edges 368 of CLK signal 332.

Thus, the hierarchical memory training approach illustrated in scenarios 200 and 300 yields the same timing offset for the CTL signal as the non-hierarchical approach illustrated in scenario 100, but with the hierarchical approach needing to generate only 47 samples of the CTL signal (33 coarse sweep samples plus 14 fine sweep samples) instead of the 256 samples generated in the non-hierarchical approach, which is an over five times reduction in the number of samples generated and sample generation time.

The methods described herein can be implemented by computer-executable instructions that are part of a computing system's power-on startup sequence. In some embodiments, the methods are executed by BIOS (Basic Input/Output System) code. In other embodiments, the methods are executed by the Memory Reference Code (MRC) portion of BIOS code. The computer-executable instructions implementing the methods disclosed herein can specify the reference signal a base timing interval is to be based on, the period of such a reference signal, a number of divisions to the reference signal is to be divided by to determine the base timing interval, and a multiple that is to be applied to the base timing interval for one or more of non-clock memory signal for which memory training is to be performed. A multiple can be associated with one, several, or all non-clock memory signals, and different multiples can be associated with different non-clock memory signals. In some embodiments, the adjustable timing offset interval is expressed in a manner other than a multiple of a base timing interval. For example, the adjustable timing offset interval can be specified in time units (e.g., nanoseconds, picoseconds) or as a percentage of the period of a non-clock memory signal.

In the memory training scenarios illustrated in FIGS. 1-3, samples of the non-clock memory signals are captured at the rising edge of a memory clock signal. In other embodiments, non-clock memory signals can be captured during memory training on the falling edge of a memory clock signal. Further, it is not necessary that non-clock memory signals be asserted to have the polarity indicated in FIGS. 1-3. In some embodiments, the falling edge of a non-clock memory signal can be captured at a lower adjustable timing offset than the rising edge of the non-clock memory signal. For example, with reference to FIG. 1, the rising and falling edges of CTL signal having the opposite polarity of the CTL waveforms 106 could be captured at the 245th and 117th adjustable timing offsets, respectively.

In some embodiments, the multiple of the base timing interval used in a coarse or hierarchical memory training approach can be user-defined. An adjustable timing offset interval can be user-defined as well (as a multiple of a base timing interval, as a time period, a percentage of a non-clock memory signal, etc.). User-specified multiples can be provided through the editing of BIOS code, through adjustment of multiples presented to a user during power-on startup of a computing system, or by other approaches. In such embodiments, a user can specify different multiples for different non-clock memory signals. Allowing a user to adjust these multiples allows the user to adjust the memory training time depending on different platform (such as different DIMM configurations) needs.

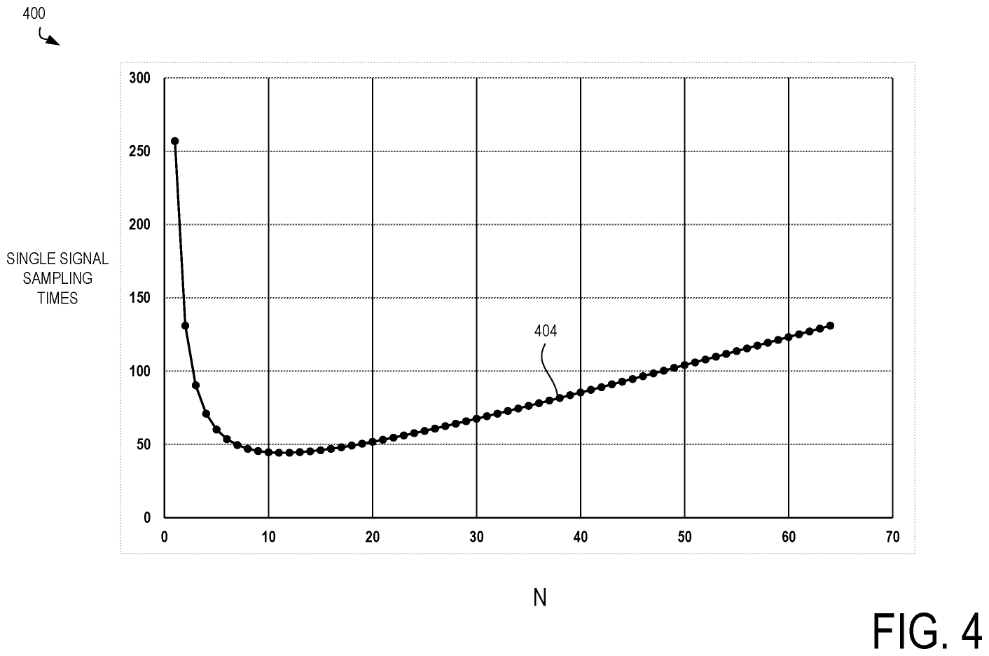

FIG. 4 is a graph illustrating the dependency of the number of non-clock memory signal samples captured during a hierarchical memory training approach based on the coarseness of the coarse sweep sampling step. Graph 400 illustrates the number of single signal sample timings that are to be incurred in a hierarchical memory training approach for a non-clock memory signal whose period comprises 256 base timing intervals (e.g., CTL signals 104, 204, 304). The number of single signal sampling times can be represented by PN/N+1+2(N−1), where PN is the number of base time intervals in a period of a non-clock memory signal and N is the base time interval multiple for the non-clock memory signal. The term PN/N+1 is the number of single signal sampling times in the coarse sweep sampling step and the term 2(N−1) is the number of single signal sampling times in the fine sweep sampling step. Curve 404 indicates that the reduction in memory training time in using a hierarchical approach over a full sweep sampling approach (N=1) is greatest when the multiple N is approximately in the range of 8-16. A multiple of N=1 can be chosen by a user for memory training results to be consistent with a non-hierarchical approach.

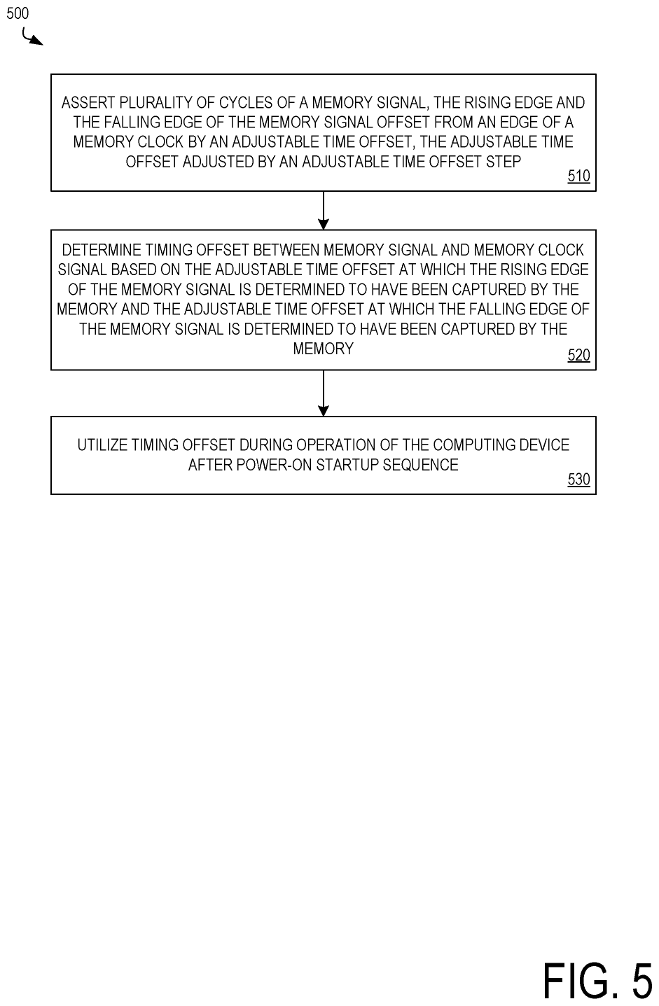

FIG. 5 is an example method of performing coarse memory training. The method 500 can be performed by MRC BIOS code of a server computer during power-on startup of the server computer. At 510, a plurality of cycles of a non-clock memory signal are asserted to a memory of a computing device, the rising edge and the falling edge of the non-clock memory signal for an individual cycle offset from an edge of a memory clock signal asserted to the memory by an adjustable timing offset, the adjustable timing offset adjusted by an adjustable timing offset interval after the assertion of one or more cycles of the plurality of cycles to the memory. At 520, a timing offset between the non-clock memory signal and the memory clock signal is determined based on the adjustable timing offset at which the rising edge of the non-clock memory signal is determined to have been captured by the memory and the adjustable timing offset at which the falling edge of the non-clock memory signal is determined to have been captured by the memory. At 530, the timing offset is utilized while transmitting the memory signal to the memory during the operation of the computing device. The method 500 can comprise additional elements in other embodiments. For example, in one embodiment, the method 500 can further comprise determining the base timing interval by dividing the period of a reference signal by a number of divisions for the reference signal.

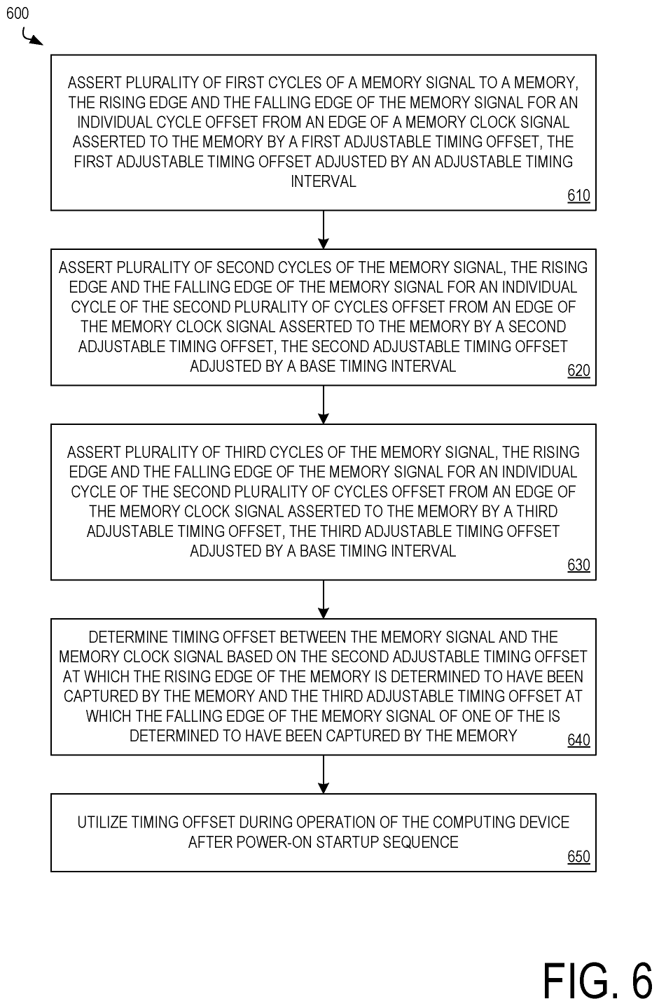

FIG. 6 is an example method of performing hierarchical memory training. The method 600 can be performed by a laptop computer during the power-on startup sequence of the laptop computer. At 610, a plurality of first cycles of a non-clock memory signal are asserted to a memory of a computing device, the rising edge and the falling edge of the non-clock memory signal for an individual cycle offset from an edge of a memory clock signal asserted to the memory by a first adjustable timing offset, the first adjustable timing offset adjusted by an adjustable timing offset interval after assertion of one or more cycles of the plurality of first cycles to the memory. At 620, a plurality of second cycles of the non-clock memory signal are asserted to the memory, the rising edge and the falling edge of the non-clock memory signal for an individual cycle of the second plurality of cycles offset from an edge of the memory clock signal asserted to the memory by a second adjustable timing offset, the second adjustable timing offset adjusted by a base timing interval after assertion of one or more second cycles of the plurality of cycles to the memory. At 630, a plurality of third cycles of the non-clock memory signal are asserted to the memory, the rising edge and the falling edge of the non-clock memory signal for an individual cycle of the third plurality of cycles offset from an edge of the memory clock signal asserted to the memory by a third adjustable timing offset, the third adjustable timing offset adjusted by the base timing interval after assertion of one or more third cycles of the plurality of cycles to the memory. At 640, a timing offset between the non-clock memory signal and the memory clock signal is determined based on the second adjustable timing offset at which the rising edge of the non-clock memory signal is determined to have been captured by the memory and the third adjustable timing offset at which the falling edge of the non-clock memory signal is determined to have been captured by the memory. At 650, the timing offset is utilized while transmitting the memory signal to the memory during operation of the computing device. The method 600 can comprise additional elements in other embodiments. For example, in one embodiment, the method 600 can further comprise determining as a starting offset time for the second adjustable timing offset, the first adjustable timing offset at which the rising edge or the falling edge of the non-clock memory signal is determined to have been captured by the memory; and determining as a starting offset time for the third adjustable timing offset, the first adjustable offset at which the other of the rising edge or the falling edge of the non-clock memory signal is determined to have been captured by the memory.

The technologies described herein can be performed by or implemented in any of a variety of computing systems, including mobile computing systems (e.g., smartphones, handheld computers, tablet computers, laptop computers, portable gaming consoles, 2-in-1 convertible computers, portable all-in-one computers), non-mobile computing systems (e.g., desktop computers, servers, workstations, stationary gaming consoles, set-top boxes, smart televisions, rack-level computing solutions (e.g., blade, tray, or sled computing systems)), and embedded computing systems (e.g., computing systems that are part of a vehicle, smart home appliance, consumer electronics product or equipment, manufacturing equipment). As used herein, the term “computing system” includes computing devices and includes systems comprising multiple discrete physical components. In some embodiments, the computing systems are located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

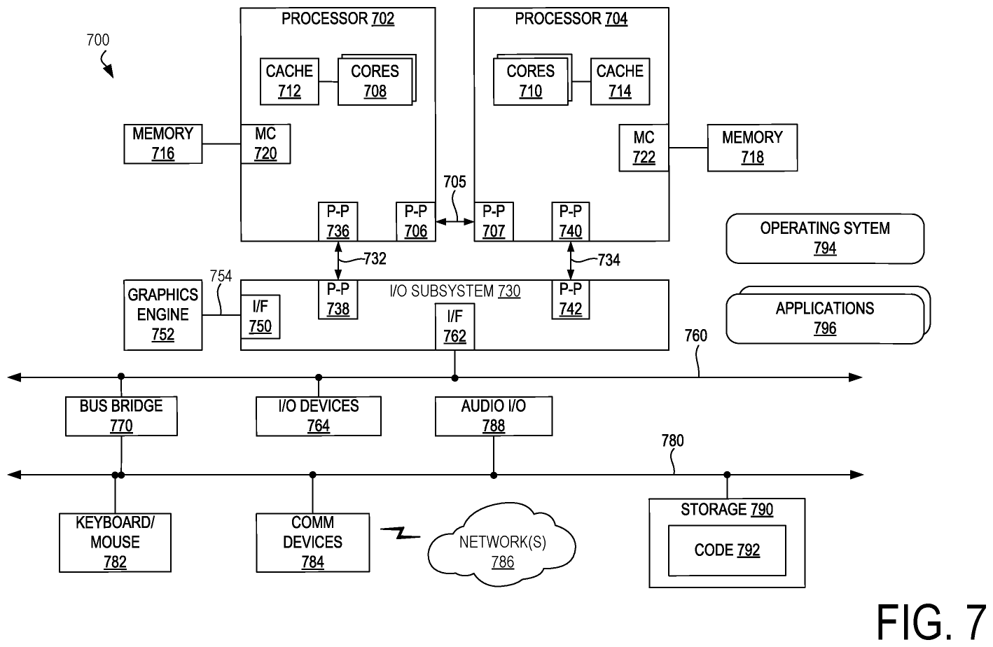

FIG. 7 a block diagram of an example computing system in which technologies described herein may be implemented. Generally, components shown in FIG. 7 can communicate with other shown components, although not all connections are shown, for ease of illustration. The computing system 700 is a multiprocessor system comprising a first processor unit 702 and a second processor unit 704 comprising point-to-point (P-P) interconnects. A point-to-point (P-P) interface 706 of the processor unit 702 is coupled to a point-to-point interface 707 of the processor unit 704 via a point-to-point interconnection 705. It is to be understood that any or all of the point-to-point interconnects illustrated in FIG. 7 can be alternatively implemented as a multi-drop bus, and that any or all buses illustrated in FIG. 7 could be replaced by point-to-point interconnects.

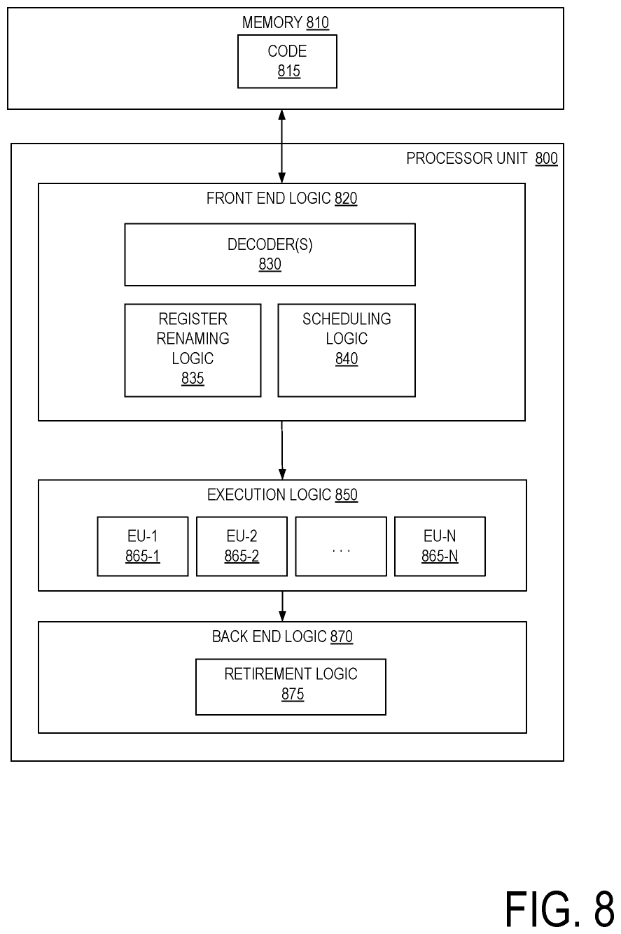

The processor units 702 and 704 comprise multiple processor cores. Processor unit 702 comprises processor cores 708 and processor unit 704 comprises processor cores 710. Processor cores 708 and 710 can execute computer-executable instructions in a manner similar to that discussed below in connection with FIG. 8, or other manners.

Processor units 802 and 804 further comprise cache memories 812 and 814, respectively. The cache memories 812 and 814 can store data (e.g., instructions) utilized by one or more components of the processor units 802 and 804, such as the processor cores 808 and 810. The cache memories 812 and 814 can be part of a memory hierarchy for the computing system 800. For example, the cache memories 812 can locally store data that is also stored in a memory 816 to allow for faster access to the data by the processor unit 802. In some embodiments, the cache memories 812 and 814 can comprise multiple cache levels, such as level 1 (L1), level 2 (L2), level 3 (L3), level 4 (L4) and/or other caches or cache levels. In some embodiments, one or more levels of cache memory (e.g., L2, L3, L4) can be shared among multiple cores in a processor unit or among multiple processor units in an integrated circuit component. In some embodiments, the last level of cache memory on an integrated circuit component can be referred to as a last level cache (LLC). One or more of the higher levels of cache levels (the smaller and faster caches) in the memory hierarchy can be located on the same integrated circuit die as a processor core and one or more of the lower cache levels (the larger and slower caches) can be located on an integrated circuit dies that are physically separate from the processor core integrated circuit dies.

Although the computing system 700 is shown with two processor units, the computing system 700 can comprise any number of processor units. Further, a processor unit can comprise any number of processor cores. A processor unit can take various forms such as a central processing unit (CPU), a graphics processing unit (GPU), general-purpose GPU (GPGPU), accelerated processing unit (APU), field-programmable gate array (FPGA), neural network processing unit (NPU), data processor unit (DPU), accelerator (e.g., graphics accelerator, digital signal processor (DSP), compression accelerator, artificial intelligence (AI) accelerator), controller, or other types of processing units. As such, the processor unit can be referred to as an XPU (or xPU). Further, a processor unit can comprise one or more of these various types of processing units. In some embodiments, the computing system comprises one processor unit with multiple cores, and in other embodiments, the computing system comprises a single processor unit with a single core. As used herein, the terms “processor unit” and “processing unit” can refer to any processor, processor core, component, module, engine, circuitry, or any other processing element described or referenced herein.

In some embodiments, the computing system 700 can comprise one or more processor units that are heterogeneous or asymmetric to another processor unit in the computing system. There can be a variety of differences between the processing units in a system in terms of a spectrum of metrics of merit including architectural, microarchitectural, thermal, power consumption characteristics, and the like. These differences can effectively manifest themselves as asymmetry and heterogeneity among the processor units in a system.

The processor units 702 and 704 can be located in a single integrated circuit component (such as a multi-chip package (MCP) or multi-chip module (MCM)) or they can be located in separate integrated circuit components. An integrated circuit component comprising one or more processor units can comprise additional components, such as embedded DRAM, stacked high bandwidth memory (HBM), shared cache memories (e.g., L3, L4, LLC), input/output (I/O) controllers, or memory controllers. Any of the additional components can be located on the same integrated circuit die as a processor unit, or on one or more integrated circuit dies separate from the integrated circuit dies comprising the processor units. In some embodiments, these separate integrated circuit dies can be referred to as “chiplets”. In some embodiments where there is heterogeneity or asymmetry among processor units in a computing system, the heterogeneity or asymmetric can be among processor units located in the same integrated circuit component. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Processor units 702 and 704 further comprise memory controller logic (MC) 720 and 722. As shown in FIG. 7, MCs 720 and 722 control memories 716 and 718 coupled to the processor units 702 and 704, respectively. The memories 716 and 718 can comprise various types of volatile memory (e.g., dynamic random-access memory (DRAM), static random-access memory (SRAM)) and/or non-volatile memory (e.g., flash memory, chalcogenide-based phase-change non-volatile memories), and comprise one or more layers of the memory hierarchy of the computing system. The memories 716 and 718 can be pooled memory, far memory, tiered memory, or another remote memory resource for an application, operating system, etc., that is executing on a remote system (a computing system physically separate from the one comprising memories 716 and 718). While MCs 720 and 722 are illustrated as being integrated into the processor units 702 and 704, in alternative embodiments, the MCs can be external to a processor unit.

Processor units 702 and 704 are coupled to an Input/Output (I/O) subsystem 730 via point-to-point interconnections 732 and 734. The point-to-point interconnection 732 connects a point-to-point interface 736 of the processor unit 702 with a point-to-point interface 738 of the I/O subsystem 730, and the point-to-point interconnection 734 connects a point-to-point interface 740 of the processor unit 704 with a point-to-point interface 742 of the I/O subsystem 730. Input/Output subsystem 730 further includes an interface 750 to couple the I/O subsystem 730 to a graphics engine 752. The I/O subsystem 730 and the graphics engine 752 are coupled via a bus 754.

The Input/Output subsystem 730 is further coupled to a first bus 760 via an interface 762. The first bus 760 can be a Peripheral Component Interconnect Express (PCIe) bus or any other type of bus. Various I/O devices 764 can be coupled to the first bus 760. A bus bridge 770 can couple the first bus 760 to a second bus 780. In some embodiments, the second bus 780 can be a low pin count (LPC) bus. Various devices can be coupled to the second bus 780 including, for example, a keyboard/mouse 782, audio I/O devices 788, and a storage device 790, such as a hard disk drive, solid-state drive, or another storage device for storing computer-executable instructions (code) 792 or data. The code 792 can comprise computer-executable instructions for performing methods described herein. Additional components that can be coupled to the second bus 780 include communication device(s) 784, which can provide for communication between the computing system 700 and one or more wired or wireless networks 786 (e.g. Wi-Fi, cellular, or satellite networks) via one or more wired or wireless communication links (e.g., wire, cable, Ethernet connection, radio-frequency (RF) channel, infrared channel, Wi-Fi channel) using one or more communication standards (e.g., IEEE 702.11 standard and its supplements).

In embodiments where the communication devices 784 support wireless communication, the communication devices 784 can comprise wireless communication components coupled to one or more antennas to support communication between the computing system 700 and external devices. The wireless communication components can support various wireless communication protocols and technologies such as Near Field Communication (NFC), IEEE 1002.11 (Wi-Fi) variants, WiMax, Bluetooth, Zigbee, 4G Long Term Evolution (LTE), Code Division Multiplexing Access (CDMA), Universal Mobile Telecommunication System (UMTS) and Global System for Mobile Telecommunication (GSM), and 5G broadband cellular technologies. In addition, the wireless modems can support communication with one or more cellular networks for data and voice communications within a single cellular network, between cellular networks, or between the computing system and a public switched telephone network (PSTN).

The system 700 can comprise removable memory such as flash memory cards (e.g., SD (Secure Digital) cards), memory sticks, Subscriber Identity Module (SIM) cards). The memory in system 700 (including caches 712 and 714, memories 716 and 718, and storage device 790) can store data and/or computer-executable instructions for executing an operating system 794, application programs 796 or BIOS code. Example data includes web pages, text messages, images, sound files, and video data to be sent to and/or received from one or more network servers or other devices by the system 700 via the one or more wired or wireless networks 786, or for use by the system 700. The system 700 can also have access to external memory or storage (not shown) such as external hard drives or cloud-based storage.

The operating system 794 can control the allocation and usage of the components illustrated in FIG. 7 and support the one or more application programs 796. The application programs 796 can include common computing system applications (e.g., email applications, calendars, contact managers, web browsers, messaging applications) as well as other computing applications.

In some embodiments, a hypervisor (or virtual machine manager) operates on the operating system 794 and the application programs 796 operate within one or more virtual machines operating on the hypervisor. In these embodiments, the hypervisor is a type-2 or hosted hypervisor as it is running on the operating system 794. In other hypervisor-based embodiments, the hypervisor is a type-1 or “bare-metal” hypervisor that runs directly on the platform resources of the computing system 794 without an intervening operating system layer.

In some embodiments, the applications 796 can operate within one or more containers. A container is a running instance of a container image, which is a package of binary images for one or more of the applications 796 and any libraries, configuration settings, and any other information that one or more applications 796 need for execution. A container image can conform to any container image format, such as Docker®, Appc, or LXC container image formats. In container-based embodiments, a container runtime engine, such as Docker Engine, LXU, or an open container initiative (OCI)-compatible container runtime (e.g., Railcar, CRI-O) operates on the operating system (or virtual machine monitor) to provide an interface between the containers and the operating system 794. An orchestrator can be responsible for management of the computing system 700 and various container-related tasks such as deploying container images to the computing system 794, monitoring the performance of deployed containers, and monitoring the utilization of the resources of the computing system 794.

The computing system 700 can support various additional input devices, such as a touchscreen, microphone, monoscopic camera, stereoscopic camera, trackball, touchpad, trackpad, proximity sensor, light sensor, and one or more output devices, such as one or more speakers or displays. Any of the input or output devices can be internal to, external to, or removably attachable with the system 700. External input and output devices can communicate with the system 700 via wired or wireless connections.

The system 700 can further include at least one input/output port comprising physical connectors (e.g., USB, IEEE 1394 (FireWire), Ethernet, RS-232), and/or a power supply (e.g., battery). The computing system 700 can further comprise one or more additional antennas coupled to one or more additional receivers, transmitters, and/or transceivers to enable additional functions.

It is to be understood that FIG. 7 illustrates only one example computing system architecture. Computing systems based on alternative architectures can be used to implement technologies described herein. For example, instead of the processors 702 and 704 and the graphics engine 752 being located on discrete integrated circuits, a computing system can comprise an SoC (system-on-a-chip) integrated circuit incorporating multiple processors, a graphics engine, and additional components. Further, a computing system can connect its constituent component via bus or point-to-point configurations different from that shown in FIG. 7. Moreover, the illustrated components in FIG. 7 are not required or all-inclusive, as shown components can be removed and other components added in alternative embodiments.

FIG. 8 is a block diagram of an example processor unit 800 to execute computer-executable instructions as part of implementing technologies described herein. The processor unit 800 can be a single-threaded core or a multithreaded core in that it may include more than one hardware thread context (or “logical processor”) per processor unit.

FIG. 8 also illustrates a memory 810 coupled to the processor unit 800. The memory 810 can be any memory described herein or any other memory known to those of skill in the art. The memory 810 can store computer-executable instructions 815 (code) executable by the processor unit 800.

The processor unit comprises front-end logic 820 that receives instructions from the memory 810. An instruction can be processed by one or more decoders 830. The decoder 830 can generate as its output a micro-operation such as a fixed width micro-operation in a predefined format, or generate other instructions, microinstructions, or control signals, which reflect the original code instruction. The front-end logic 820 further comprises register renaming logic 835 and scheduling logic 840, which generally allocate resources and queues operations corresponding to converting an instruction for execution.

The processor unit 800 further comprises execution logic 850, which comprises one or more execution units (EUs) 865-1 through 865-N. Some processor unit embodiments can include a number of execution units dedicated to specific functions or sets of functions. Other embodiments can include only one execution unit or one execution unit that can perform a particular function. The execution logic 850 performs the operations specified by code instructions. After completion of execution of the operations specified by the code instructions, back-end logic 870 retires instructions using retirement logic 875. In some embodiments, the processor unit 800 allows out of order execution but requires in-order retirement of instructions. Retirement logic 875 can take a variety of forms as known to those of skill in the art (e.g., re-order buffers or the like).

The processor unit 800 is transformed during execution of instructions, at least in terms of the output generated by the decoder 830, hardware registers and tables utilized by the register renaming logic 835, and any registers (not shown) modified by the execution logic 850.

As used herein, the term “module” refers to logic that may be implemented in a hardware component or device, software or firmware running on a processor unit, or a combination thereof, to perform one or more operations consistent with the present disclosure. Software and firmware may be embodied as instructions and/or data stored on non-transitory computer-readable storage media. As used herein, the term “circuitry” can comprise, singly or in any combination, non-programmable (hardwired) circuitry, programmable circuitry such as processor units, state machine circuitry, and/or firmware that stores instructions executable by programmable circuitry. Modules described herein may, collectively or individually, be embodied as circuitry that forms a part of a computing system. Thus, any of the modules can be implemented as circuitry, such as memory training circuitry. A computing system referred to as being programmed to perform a method can be programmed to perform the method via software, hardware, firmware, or combinations thereof.

Any of the disclosed methods (or a portion thereof) can be implemented as computer-executable instructions or a computer program product. Such instructions can cause a computing system or one or more processor units capable of executing computer-executable instructions to perform any of the disclosed methods. As used herein, the term “computer” refers to any computing system, device, or machine described or mentioned herein as well as any other computing system, device, or machine capable of executing instructions. Thus, the term “computer-executable instruction” refers to instructions that can be executed by any computing system, device, or machine described or mentioned herein as well as any other computing system, device, or machine capable of executing instructions.

The computer-executable instructions or computer program products as well as any data created and/or used during implementation of the disclosed technologies can be stored on one or more tangible or non-transitory computer-readable storage media, such as volatile memory (e.g., DRAM, SRAM), non-volatile memory (e.g., flash memory, chalcogenide-based phase-change non-volatile memory) optical media discs (e.g., DVDs, CDs), and magnetic storage (e.g., magnetic tape storage, hard disk drives). Computer-readable storage media can be contained in computer-readable storage devices such as solid-state drives, USB flash drives, and memory modules. Alternatively, any of the methods disclosed herein (or a portion) thereof may be performed by hardware components comprising non-programmable circuitry. In some embodiments, any of the methods herein can be performed by a combination of non-programmable hardware components and one or more processing units executing computer-executable instructions stored on computer-readable storage media.

The computer-executable instructions can be part of, for example, an operating system of the computing system, an application stored locally to the computing system, or a remote application accessible to the computing system (e.g., via a web browser). Any of the methods described herein can be performed by computer-executable instructions performed by a single computing system or by one or more networked computing systems operating in a network environment. Computer-executable instructions and updates to the computer-executable instructions can be downloaded to a computing system from a remote server.

Further, it is to be understood that implementation of the disclosed technologies is not limited to any specific computer language or program. For instance, the disclosed technologies can be implemented by software written in C++, C#, Java, Perl, Python, JavaScript, Adobe Flash, C#, assembly language, or any other programming language. Likewise, the disclosed technologies are not limited to any particular computer system or type of hardware.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, cable (including fiber optic cable), magnetic communications, electromagnetic communications (including RF, microwave, ultrasonic, and infrared communications), electronic communications, or other such communication means.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is a method comprising asserting a plurality of cycles of a non-clock memory signal to a memory of a computing device, a rising edge and a falling edge of the non-clock memory signal for an individual cycle offset from an edge of a memory clock signal asserted to the memory by an adjustable timing offset, the adjustable timing offset adjusted by an adjustable timing offset interval after assertion of one or more cycles of the plurality of cycles to the memory; and determining a timing offset between the non-clock memory signal and the memory clock signal based on the adjustable timing offset at which the rising edge of the non-clock memory signal is determined to have been captured by the memory and the adjustable timing offset at which the falling edge of the non-clock memory signal is determined to have been captured by the memory; and utilizing the timing offset while transmitting the non-clock memory signal to the memory during operation of the computing device.

Example 2 includes the subject matter of Example 1, and wherein the determining the timing offset occurs during a power-on startup sequence of the computing device and the utilizing the timing offset occurs after the power-on startup sequence.

Example 3 includes the subject matter of claim 1 or 2, wherein the adjustable timing offset interval is a multiple of a base timing interval.

Example 4 includes the subject matter of any of Examples 1-3, and wherein the multiple is associated with the non-clock memory signal.

Example 5 includes the subject matter of any of Examples 1-4, and wherein the multiple is specified in instructions executable by one or more processing units of the computing device, the instructions to be executed during a power-on startup sequence of the computing device.

Example 6 includes the subject matter of any of Examples 1-5, and further including determining the base timing interval by dividing a period of a reference signal by a number of divisions for the reference signal.

Example 7 includes the subject matter of any of Examples 1-6, and wherein the reference signal and/or the number of divisions for the reference signal is specified in instructions executable by one or more processing units of the computing device, the instructions to be executed during a power-on startup sequence of the computing device.

Example 8 includes the subject matter of any of Examples 1-7, and wherein the reference signal is the memory clock signal.

Example 9 includes the subject matter of any of Examples 1-8, and wherein the adjustable timing offset is specified in instructions executable by one or more processing units of the computing device, the instructions to be executed during a power-on startup sequence of the computing device.

Example 10 includes the subject matter of any of Examples 1-9, and wherein the adjustable timing offset is specified in time units.

Example 11 includes the subject matter of any of Examples 1-10, and wherein the adjustable timing offset is specified as a percentage of the non-clock memory signal.

Example 12 includes the subject matter of any one of claims 1-11, wherein the adjustable timing offset interval is user-defined.

Example 13 includes the subject matter of any of Examples 1-12, and further including receiving from a user the user-defined adjustable timing offset interval.

Example 14 includes the subject matter of any of Examples 1-13, and wherein the user-defined adjustable timing offset interval is a multiple of a base time interval.

Example 15 includes the subject matter of any one of claims 1-14, wherein the timing offset is an average of the adjustable timing offset at which the rising edge of the non-clock memory signal is determined to have been captured by the memory and the adjustable timing offset at which the falling edge of the non-clock memory signal is determined to have been captured by the memory.

Example 16 is a method comprising asserting a plurality of first cycles of a non-clock memory signal to a memory of a computing device, a rising edge and a falling edge of the non-clock memory signal for an individual cycle offset from an edge of a memory clock signal asserted to the memory by a first adjustable timing offset, the first adjustable timing offset adjusted by an adjustable timing offset interval after assertion of one or more cycles of the plurality of first cycles to the memory; asserting a plurality of second cycles of the non-clock memory signal to the memory, a rising edge and a falling edge of the non-clock memory signal for an individual cycle of the second plurality of cycles offset from an edge of the memory clock signal asserted to the memory by a second adjustable timing offset, the second adjustable timing offset adjusted by a base timing interval after assertion of one or more second cycles of the plurality of second cycles to the memory; asserting a plurality of third cycles of the non-clock memory signal to the memory, a rising edge and a falling edge of the non-clock memory signal for an individual cycle of the third plurality of cycles offset from an edge of the memory clock signal asserted to the memory by a third adjustable timing offset, the third adjustable timing offset adjusted by the base timing interval after assertion of one or more third cycles of the plurality of third cycles to the memory; determining a timing offset between the non-clock memory signal and the memory clock signal based on the second adjustable timing offset at which the rising edge of the non-clock memory signal is determined to have been captured by the memory and the third adjustable timing offset at which the falling edge of the non-clock memory signal is determined to have been captured by the memory; and utilizing the timing offset while transmitting the non-clock memory signal to the memory during operation of the computing device.

Example 17 includes the subject matter of Example 16, and further including determining as a starting offset time for the second adjustable timing offset, the first adjustable timing offset at which the rising edge or the falling edge of the non-clock memory signal is determined to have been captured by the memory; and determining as a starting offset time for the third adjustable timing offset, the first adjustable offset at which the other of the rising edge or the falling edge of the non-clock memory signal is determined to have been captured by the memory.

Example 18 includes the subject matter of claim 16 or 17, wherein the determining the timing offset occurs during a power-on startup sequence of the computing device and the utilizing the timing offset occurs after the power-on startup sequence.

Example 19 includes the subject matter of any one of claims 16-18, wherein the adjustable timing offset interval is a multiple of a base timing interval.

Example 20 includes the subject matter of any of Examples 16-19, and wherein the multiple is associated with the non-clock memory signal.

Example 21 includes the subject matter of any of Examples 16-20, and wherein the multiple is specified in instructions executable by one or more processing units of the computing device, the instructions to be executed during a power-on startup sequence of the computing device.

Example 22 includes the subject matter of any of Examples 16-21, and further including determining the base timing interval by dividing a period of a reference signal by a number of divisions for the reference signal.

Example 23 includes the subject matter of any of Examples 16-22, and wherein the reference signal and/or the number of divisions for the reference signal is specified in instructions executable by one or more processing units of the computing device, the instructions to be executed during a power-on startup sequence of the computing device.

Example 24 includes the subject matter of any of Examples 16-23, and wherein the reference signal is the memory clock signal.

Example 25 includes the subject matter of any of Examples 16-24, and wherein the adjustable timing offset is specified in instructions executable by one or more processing units of the computing device, the instructions to be executed during a power-on startup sequence of the computing device.

Example 26 includes the subject matter of any of Examples 16-25, and wherein the adjustable timing offset is specified in time units.

Example 27 includes the subject matter of any of Examples 16-26, and wherein the adjustable timing offset is specified as a percentage of the non-clock memory signal.

Example 28 includes the subject matter of any one of claims 16-27, wherein the adjustable timing offset interval is user-defined.

Example 29 includes the subject matter of any of Examples 16-28, and further including receiving from a user the user-defined adjustable timing offset interval.

Example 30 includes the subject matter of any of Examples 16-29, and wherein the user-defined adjustable timing offset interval is user-defined is a multiple of a base time interval.

Example 31 includes the subject matter of any one of claims 16-30, wherein the timing offset is an average of the second adjustable timing offset at which the rising edge of the non-clock memory signal is determined to have been captured by the memory and the third adjustable timing offset at which the falling edge of the non-clock memory signal is determined to have been captured by the memory.

Example 32 includes the subject matter of claim 16, the adjustable timing offset interval is an interval of a base timing interval, wherein an ending offset time for the second adjustable timing offset and the third adjustable timing offset is the multiple of the base timing interval minus one.

Example 33 includes the subject matter of claim 1 or 16, wherein the non-clock memory signal is a first non-clock memory signal, and the method of claim 1 or 16 is performed for one or more second non-clock memory signals.

Example 34 includes the subject matter of any of Examples 16-33, and wherein the adjustable timing offset interval is a first adjustable timing offset for the first non-clock memory signal and a second adjustable timing offset interval is associated with at least one of the second non-clock memory signals, the first adjustable timing offset different than the second adjustable timing offset.

Example 35 includes the subject matter of any of Examples 16-34, and wherein a first one of the second non-clock memory signals belongs to a front-side memory bus and a second one of the second non-clock memory signals belongs to a back-side memory bus.

Example 36 is one or more computer-readable storage media storing computer-executable instructions that, when executed, cause one or more processor units of the computing device to perform any one of the methods of claims 1-35.

Example 37 is a computing device comprising one or more processor units; and one or more computer-readable storage media storing computer-executable instructions that, when executed, cause the one or more processor units to perform any one of the methods of claims 1-35.

1. A method comprising:
asserting a plurality of cycles of a non-clock memory signal to a memory of a computing device, a rising edge and a falling edge of the non-clock memory signal for an individual cycle offset from an edge of a memory clock signal asserted to the memory by an adjustable timing offset, the adjustable timing offset adjusted by an adjustable timing offset interval after assertion of one or more cycles of the plurality of cycles to the memory; and
determining a timing offset between the non-clock memory signal and the memory clock signal based on the adjustable timing offset at which the rising edge of the non-clock memory signal is determined to have been captured by the memory and the adjustable timing offset at which the falling edge of the non-clock memory signal is determined to have been captured by the memory; and
utilizing the timing offset while transmitting the non-clock memory signal to the memory during operation of the computing device.

2. The method of claim 1, wherein the determining the timing offset occurs during a power-on startup sequence of the computing device and the utilizing the timing offset occurs after the power-on startup sequence.

3. The method of claim 1, wherein the adjustable timing offset interval is a multiple of a base timing interval.

4. The method of claim 3, further comprising determining the base timing interval by dividing a period of a reference signal by a number of divisions for the reference signal.

5. The method of claim 1, wherein the adjustable timing offset is specified in computer-executable instructions executable by one or more processing units of the computing device, the computer-executable instructions to be executed during a power-on startup sequence of the computing device.

6. The method of claim 1, wherein the timing offset is an average of the adjustable timing offset at which the rising edge of the non-clock memory signal is determined to have been captured by the memory and the adjustable timing offset at which the falling edge of the non-clock memory signal is determined to have been captured by the memory.

7. A method comprising:
asserting a plurality of first cycles of a non-clock memory signal to a memory of a computing device, a rising edge and a falling edge of the non-clock memory signal for an individual cycle of the plurality of first cycles offset from an edge of a memory clock signal asserted to the memory by a first adjustable timing offset, the first adjustable timing offset adjusted by an adjustable timing offset interval after assertion of one or more cycles of the plurality of first cycles to the memory;
asserting a plurality of second cycles of the non-clock memory signal to the memory, a rising edge and a falling edge of the non-clock memory signal for an individual cycle of the second plurality of cycles offset from an edge of the memory clock signal asserted to the memory by a second adjustable timing offset, the second adjustable timing offset adjusted by a base timing interval after assertion of one or more second cycles of the plurality of second cycles to the memory;
asserting a plurality of third cycles of the non-clock memory signal to the memory, a rising edge and a falling edge of the non-clock memory signal for an individual cycle of the third plurality of cycles offset from an edge of the memory clock signal asserted to the memory by a third adjustable timing offset, the third adjustable timing offset adjusted by the base timing interval after assertion of one or more third cycles of the plurality of third cycles to the memory;
determining a timing offset between the non-clock memory signal and the memory clock signal based on the second adjustable timing offset at which the rising edge of the non-clock memory signal is determined to have been captured by the memory and the third adjustable timing offset at which the falling edge of the non-clock memory signal is determined to have been captured by the memory; and
utilizing the timing offset while transmitting the non-clock memory signal to the memory during operation of the computing device.

8. The method of claim 7, further comprising:
determining as a starting offset time for the second adjustable timing offset, the first adjustable timing offset at which the rising edge or the falling edge of the non-clock memory signal is determined to have been captured by the memory; and
determining as a starting offset time for the third adjustable timing offset, the first adjustable offset at which the other of the rising edge or the falling edge of the non-clock memory signal is determined to have been captured by the memory.

9. The method of claim 7, wherein the determining the timing offset occurs during a power-on startup sequence of the computing device and the utilizing the timing offset occurs after the power-on startup sequence.

10. The method of claim 7, wherein the adjustable timing offset interval is a multiple of a base timing interval.

11. The method of claim 10, wherein the multiple is associated with the non-clock memory signal.

12. The method of claim 10, further comprising determining the base timing interval by dividing a period of a reference signal by a number of divisions for the reference signal.

13. The method of claim 12, wherein the reference signal and/or the number of divisions for the reference signal is specified in computer-executable instructions executable by one or more processing units of the computing device, the computer-executable instructions to be executed during a power-on startup sequence of the computing device.

14. The method of claim 7, wherein the adjustable timing offset is specified in computer-executable instructions executable by one or more processing units of the computing device, the computer-executable instructions to be executed during a power-on startup sequence of the computing device.

15. The method of claim 7, wherein the adjustable timing offset interval is user-defined.

16. The method of any claim 7, wherein the timing offset is an average of the second adjustable timing offset at which the rising edge of the non-clock memory signal is determined to have been captured by the memory and the third adjustable timing offset at which the falling edge of the non-clock memory signal is determined to have been captured by the memory.

17. The method of claim 7, wherein the non-clock memory signal is a first non-clock memory signal, and the method of claim 7 is performed for one or more second non-clock memory signals.

18. The method of claim 17, wherein the adjustable timing offset interval is a first adjustable timing offset for the first non-clock memory signal and a second adjustable timing offset interval is associated with at least one of the second non-clock memory signals, the first adjustable timing offset different than the second adjustable timing offset.

19. One or more computer-readable storage media storing computer-executable instructions that, when executed, cause one or more processor units of a computing device to:
assert a plurality of cycles of a non-clock memory signal to a memory of a computing device, a rising edge and a falling edge of the non-clock memory signal for an individual cycle offset from an edge of a memory clock signal asserted to the memory by an adjustable timing offset, the adjustable timing offset to be adjusted by an adjustable timing offset interval after assertion of one or more cycles of the plurality of cycles to the memory; and
determine a timing offset between the non-clock memory signal and the memory clock signal based on the adjustable timing offset at which the rising edge of the non-clock memory signal is to be determined to have been captured by the memory and the adjustable timing offset at which the falling edge of the non-clock memory signal is to be determined to have been captured by the memory; and
utilize the timing offset while transmitting the non-clock memory signal to the memory during operation of the computing device.

20. The one or more computer-readable storage media of claim 19, wherein to determine the timing offset occurs during a power-on startup sequence of the computing device and to utilize the timing offset occurs after the power-on startup sequence.

21. The one or more computer-readable storage media of claim 19, wherein the timing offset is an average of the adjustable timing offset at which the rising edge of the non-clock memory signal is determined to have been captured by the memory and the adjustable timing offset at which the falling edge of the non-clock memory signal is determined to have been captured by the memory.

22. One or more computer-readable storage media storing computer-executable instructions that, when executed, cause one or more processor units of a computing device to:
assert a plurality of first cycles of a non-clock memory signal to a memory of a computing device, a rising edge and a falling edge of the non-clock memory signal for an individual cycle of the plurality of first cycles offset from an edge of a memory clock signal asserted to the memory by a first adjustable timing offset, the first adjustable timing offset to be adjust by an adjustable timing offset interval after assertion of one or more cycles of the plurality of first cycles to the memory;
assert a plurality of second cycles of the non-clock memory signal to the memory, a rising edge and a falling edge of the non-clock memory signal for an individual cycle of the second plurality of cycles offset from an edge of the memory clock signal asserted to the memory by a second adjustable timing offset, the second adjustable timing offset to be adjusted by a base timing interval after assertion of one or more second cycles of the plurality of second cycles to the memory;
assert a plurality of third cycles of the non-clock memory signal to the memory, a rising edge and a falling edge of the non-clock memory signal for an individual cycle of the third plurality of cycles offset from an edge of the memory clock signal asserted to the memory by a third adjustable timing offset, the third adjustable timing offset to be adjusted by the base timing interval after assertion of one or more third cycles of the plurality of third cycles to the memory;
determine a timing offset between the non-clock memory signal and the memory clock signal based on the second adjustable timing offset at which the rising edge of the non-clock memory signal is to be determined to have been captured by the memory and the third adjustable timing offset at which the falling edge of the non-clock memory signal is to be determined to have been captured by the memory; and
utilize the timing offset while transmitting the non-clock memory signal to the memory during operation of the computing device.

23. The one or more computer-readable storage media of claim 22, the instructions to further cause the one or more processing units to:
determine as a starting offset time for the second adjustable timing offset, the first adjustable timing offset at which the rising edge or the falling edge of the non-clock memory signal is to be determined to have been captured by the memory; and
determine as a starting offset time for the third adjustable timing offset, the first adjustable offset at which the other of the rising edge or the falling edge of the non-clock memory signal is to be determined to have been captured by the memory.

24. The one or more computer-readable storage media of claim 22, wherein to determine the timing offset is to occur during a power-on startup sequence of the computing device and to utilize the timing offset is to occur after the power-on startup sequence.

25. The one or more computer-readable storage media of claim 22, wherein the timing offset is an average of the second adjustable timing offset at which the rising edge of the non-clock memory signal is to be determined to have been captured by the memory and the third adjustable timing offset at which the falling edge of the non-clock memory signal is to be determined to have been captured by the memory.
